(19) United States
(12) Patent Application Publication
(10) Pub. No.: US 2025/0200591 A1
(43) Pub. Date: Jun. 19, 2025

(54) Automated product design using generative AI and attitudinal data assets

(71) Applicant: Zappistore Limited, London (GB)

(72) Inventors: Steven Phillips, London (GB); Donovan Kennedy, Kent (GB)

(21) Appl. No.: 18/982,567

(22) Filed: Dec. 16, 2024

(30) Foreign Application Priority Data
Dec. 15, 2023 (GB) 2319237.0

(51) Int. Cl. G06Q 30/0201

(52) U.S. Cl. CPC G06Q 30/0201

(57) ABSTRACT

The subject matter herein provides a method of product concept modification, the method comprising: receiving a product concept; identifying factors from on an attitudinal data asset in relation to the received product concept; providing the product concept and the factors as an input to generative AI to produce a modified product concept. The subject matter also relates to a method and system for automated manufacture in which the generated or modified concept is provided to a manufacturing facility or function. The subject matter also relates to products produced in this manner.

### BACKGROUND

The subject matter herein relates generally to a method of product design and a product produced according to the design. The subject matter also relates to process design and a process optimized according to the process design.

The use of consumer insight data is well-known and typically such data is used the world over to enable producers of products and services to generate and modify products and services to suit their potential markets.

From the perspective of a supplier, e.g. a company or person producing a service or product for sale the generation of product ideas can be achieved in any number of known ways.

One typical route that relies upon the use of insight data is generally as follows. The following description is with reference to a company producing a product although this is for the purpose of explanation only. It will be understood that the process and method apply to a company or individual involved in generating a process as well.

Initially, referring to FIG. 1 which shows schematically a product design process, a company management might instruct 2 its marketing team to create or refine a concept, asset, advertisement, brand or design for a new consumer product or service which has not previously been revealed to the market. For example, the instruction in respect of the new product might be: “We want to create a new beer brand that appeals to men aged 18-35 in Texas”.

Conventionally, the company's marketing team creates 4 a draft document containing text, images, video, design specifications, taglines, branding assets, etc., setting out details of the potential new product. This document with the various product descriptions and classifications is defined as a “concept” in a product or process lifecycle.

Prior to commercial launch of the product, the company typically tests the market appeal of the proposed new product, its proposed advertising and/or its proposed packaging. This is usually done in by testing 6 the concept in one or more consumer insights surveys.

The company identifies the kind of consumers to whom it wants the new product to appeal, e.g. in the case of the product specified above, this could be: “males, aged 18-35, based in Texas, who like drinking beer.”

The surveys then generated by an insight team, which could be internal to the company or acting externally as an agent, would be targeted at individuals with those characteristics. The survey would typically reveal the concept to consumers in the group and measure and gather data relating to the responses from group members. This gathered data set might be referred to as the “Insights”.

The Insights are gathered together and are typically displayed 8 within a report for explaining to the marketing team of the company how consumers responded to the concept and how the concept compares to other stimuli within the same genre of product or service.

The company's marketing team is then able to review the report and manually update 10 and refine the concept to improve the market appeal of the new product before commercial launch. Depending on timescales and project budgets, the process of steps 6 to 10 can be repeated any number of times or alternatively, the output of the improved concept after manual modification based on the insight report is output 12 as a product (or process) design.

The improved new product design 12 is provided to a manufacturing process 14, either directly automatically or via human interaction and the product is manufactured for launch to the public.

This is a well-known sequence of steps that works well and produces product designs for manufacture in which the originating individual or company can have some degree of commercial confidence. However, improvements in the process are desired.

### SUMMARY

According to a first aspect of the subject matter herein, there is provided a method of product concept design, the method comprising: receiving a product concept; identifying themes and their relevance based on an attitudinal data asset in relation to the received product concept; providing the product concept and the identified themes and their relevance as an input to generative AI to produce the optimized product concept design. Attitudinal data is information about customer feelings, motivations, and opinions toward a product, a brand, or customer experience.

The subject matter herein provides a method of product design or product concept design which enables optimization of the concept or design using a generative Artificial Intelligence (AI). That said, the method goes well beyond this because it relies not only on the use of generative AI but also factors derived from an attitudinal data asset in relation to the received product concept. The factors could typically be themes from the collected data that forms the attitudinal data asset that correspond to improved or worsening performance.

By testing the outputs of the process, the effect of the use of the factors, such as the themes and their relevance, significantly enhances and improves the perception and reception of products or concepts so generated.

In one example, the output is provided as a design directly to a manufacturing facility enabling a streamlined and simplified robust method for product design optimization.

Preferably, the generated design is output to a manufacturing facility enabling the simplified manufacture of an optimized product.

The method can apply to concepts related to any sort of product, such as would relate to food and drink packaging (including alcohol and tobacco), household, health and personal care products, apparel and accessories, veterinary products, consumer electronics and technology products, telecommunications and social media services, gaming products and services, automotives, travel services, and entertainment and media.

In one example embodiment, the process of concept design is executed using one or more AI agents.

Preferably, a facilitator agent is arranged to select desired or required agents for a particular concept or design generation process. AI agents not required for the process are specifically not included thereby maximizing the efficiency of the automated design process.

According to a second aspect of the subject matter herein. there is provided a method of generating a product concept, the method comprising identifying factors from an attitudinal data asset relating to a concept to be created; providing the factors to a generative AI, and producing the concept with the generative AI.

According to a third aspect of the subject matter herein, there is provided a method of generating a product design for manufacture, the method comprising identifying a target for use of the product to be manufactured; extracting themes from a data set to appeal to the target; provide the extracted themes as an input to a generative language model prompt; execute the language model prompt to generate a product design based on the inputs to the generative language prompt.

According to a further aspect of the subject matter, there is provided a method of manufacture of a bottled product, the method comprising, generating a product design according to a product concept produced by identifying factors from on an attitudinal data asset in relation to the bottled product concept; providing the bottled product concept and the factors as an input to generative AI to produce a modified product concept relating to the bottled product; manufacturing the bottled product according to the design.

The subject matter herein provides a method of manufacture of a product such as a bottled product which is particularly suitable for having a concept generated based on the use of identified factors from an attitudinal data asset and being used in combination with generative AI. The product design created in accordance with the method is preferably output to an automated product manufacturing facility which is then able to manufacture the improved generated product accordingly. The method can be used for all forms of bottled products which can include foods, drinks, toiletries, lubricants, cleaning agents, soaps, perfumes and many more. The skilled person will understand the wide applicability of the method to bottled products.

According to a further aspect, there is provided a method of manufacture of a container having an opening and body for storing a gas, liquid or solid, the method comprising, generating a design for the container according to a product concept produced by identifying factors from on an attitudinal data asset in relation to the container concept; providing the container concept and the factors as an input to generative AI to produce a modified container concept relating to the container; and manufacturing the container according to the design

Preferably, the product concept of the container includes factors relating one or more of the physical dimensions of the container and the surface appearance of the container. The surface appearance can include the texture, the patterning, the color the material and any other factors that affect the external surface appearance of the container.

The method enables an improved product design to be generated automatically based on factors derived from an attitudinal data asset. The surface appearance and the three dimensional configuration of a product such as a container can interact significantly to determine how it is perceived by a user. The use of factors obtained from an attitudinal data set in combination with a generative AI engine ensures that the combination of the surface and three dimensional appearance of the generated product are optimized.

Further details regarding the subject matter herein are set forth in the disclosure and drawings.

### BRIEF DESCRIPTION OF DRAWINGS

FIG. 1 is a schematic flowchart showing a known process of concept design and manufacture in relation to a product concept;

FIG. 2 is a schematic flowchart showing an exemplary process of concept design and modification and manufacture in relation to a product concept;

FIG. 3 is a schematic flowchart showing an exemplary process of concept creation in relation to a product concept;

FIGS. 4A to 4C show exemplary outputs from the processes of FIGS. 1 and 2;

FIGS. 5 and 6 show results for the product concepts shown in FIGS. 4A to 4C;

FIG. 7 is a schematic view of a manufacturing facility; and

FIG. 8 is a schematic view of a set of AI generation agents used in a representative automated process of concept or product design generation.

### DETAILED DESCRIPTION

As noted above, the subject matter herein is an improved method of product design and product manufacture is achieved using a combination of market gathered insight data with a generative AI system. The product design and manufacturing method and system provides additional advantages by combining the use of themes extracted from an attitudinal data set and/or market insight data with generative AI. Results, discussed and shown below, demonstrate that the output in terms of subsequent user interaction exceeds what would be expected simply from the use of AI or insight data using known methods of concept generation and subsequent manufacture of the generated product designs.

The improvements in terms of technically measurable output goes beyond the sum of the improvements expected from using, individually, extracted themes/insight data or generative AI. The output of the process goes beyond the mere sum of the combination of the improvements, demonstrating a synergistic technical effect. Manufactured products that are produced according to designs or concepts generate in the specified manner represent a technical improvement on the products manufactured using either of the two methodologies alone.

Furthermore, although the description thus far has been in relation to the production of products, it applies similarly to processes. For example, a technical manufacturing process can itself be thought of as a concept in the manner defined herein.

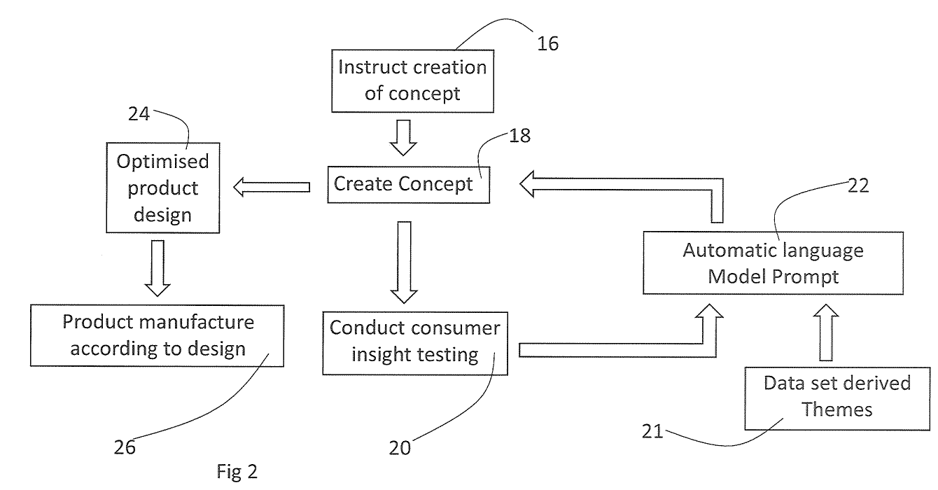

The improved process is now described in detail with reference to the example of FIG. 2.

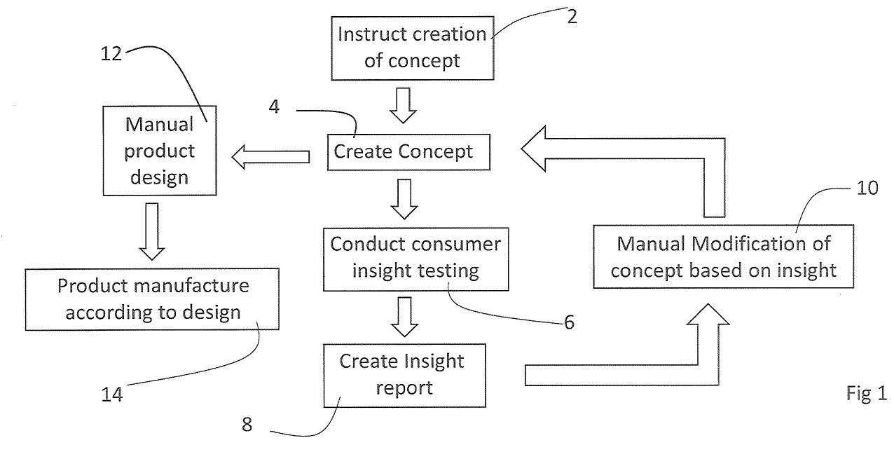

The novel method and process disclosed herein, in a general sense, removes the necessity for generating an insight report (as described above with reference to FIG. 1). Providing manual modification of a concept based on interpretation of the report, can be avoided entirely. Thus, steps 8 and 10 from FIG. 1 can be avoided and instead a step of providing an automatic language model prompt is used, to be described in greater detail below.

Referring to FIG. 2, again creation of a concept 16 is instructed and at step 18 the concept is created, analogous to steps 2 and 4 of the method of FIG. 1.

Consumer insight testing is preferably performed at step 20 and the outputs provided to an automatic language model prompt modification stage 22. The automatic language model prompt stage 22 will typically use generative AI together with an existing attitudinal data asset by identifying factors such as themes and their relevance. The themes 21 are provided as an input to the automatic language model prompt 22. Optionally, results of consumer insight testing can also be provided as inputs to the automatic language model prompt. A more detailed example will be given below, but the skilled person will understand that what is being used is a combination of generative AI with intelligence from an existing data asset to improve significantly the output from the generative AI alone.

The process 22 of executing the automatic language model prompt modification can be repeated any desired number of times in response to updating of consumer insight testing 20 or data set derived themes.

Referring again to FIG. 2, again it can be seen that the output from the concept creation stage 18 can be provided as an optimized product design 24 for onward forwarding directly to manufacture 26, or if desired the cycle of stages 18, 20 and 22 a can be repeated.

The process for optimized product design can be performed remotely, e.g., in the cloud, or it can be performed locally to a manufacturing facility. In either case it is possible, and well known to a skilled person how the required design details for manufacture can be provided in an appropriate format to the manufacturing facility. This could depend on the type of product to be manufactured but could typically include a data file specifying one or more of the features, components, ingredients, or parameters, etc., of the product to be manufactured. These can of course vary depending on what the product is as will be understood by a skilled person.

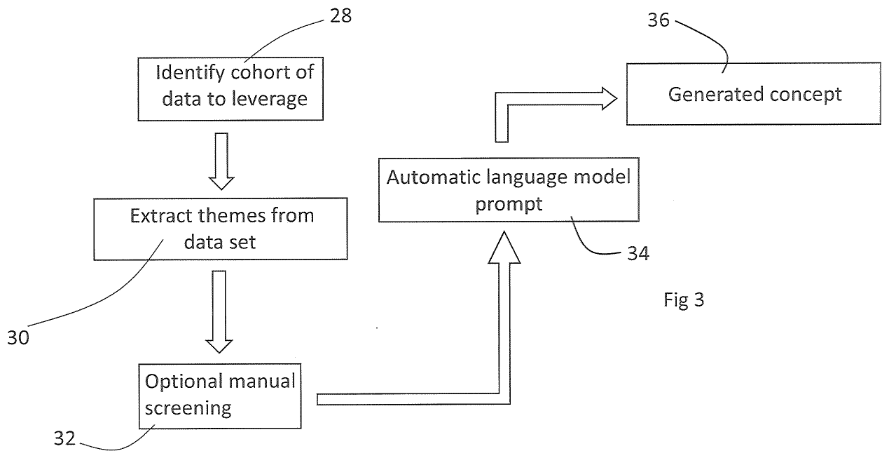

A further example is described with reference to FIG. 3.

In this example, instead of modifying an initial concept created in a conventional way, the method is used to create a new concept itself based on, amongst other factors, the category and brand. Like the example of FIG. 2, improved product is produced using a combination of market gathered insight data with a generative AI system. In this example, the concept itself is generated without initial human design input.

Referring to the FIG. 3, at 28 a user is prompted to identify a relevant cohort of data to leverage. Typically, but depending on product, this could include a country, category, brand and other basic demographics (such as age and gender).

This information is used to extract 30 response themes from an existing data asset, as well as their corresponding attitudinal metrics. The user can then optionally screen 32 the themes for appropriateness, and the selection is injected into a language model prompt 34. The prompt itself is an instruction to generate a new concept or idea, with the same parameters as the user defined scope, and to ensure that the selected themes are either emphasized or de-emphasized as appropriate.

Other attributes relevant to the concept, such as the tone of voice can also be captured and injected into the prompt at step 34.

The prompt 34 is then arranged and configured, based on generative AI and the input themes determined from the existing data set to generate the concept 36 in a specified or selected format.

The user can optionally (manually) adjust any of the inputs, e.g. at step 32, that are used to generate the concept. Alternatively, or as well, if the user so desires manual modifications can be made to the generated concept 36 itself. A user is able manually to specify desired parameters or qualities associated with the concept, either to be included within and/or excluded from the concept to be generated.

The concept as generated at step 36 may typically be simply a description and so this is then preferably provided to an image generation API for creation of an accompanying image. Regarding manual modifications, an example could be, if, say a concept or design for a snack that is designed to offer a delayed energy release is generated, but the owner or company for whom the snack concept or product is being designed does not want the word “protein” to be explicitly used in the generated concept. In such a case, the prompt can be manually amended to instruct this, e.g. “Do not use the term “protein” in the concept”.

Although not shown in FIG. 3, it will be understood that insight testing can be performed on the generated concept and this used as an input again to the automatic language model prompt.

It will be understood that the concept as prepared can be used itself as an input to the process described above with reference to FIG. 2, i.e., at step 18 in FIG. 2.

Preferably, the present method utilizes an existing data insight data set including optionally attitudinal data asset by identifying themes from collected data that correspond with improved or worsening performance, and injects those themes (and their relevance) into a language model prompt, which is an instruction designed to generate or improve a concept or product that maximizes (or minimizes) the identified themes.

It will be appreciated from the description above, that the approach can be used to either generate a new concept, where the scope of data queried corresponds with the user defined country, category and brand, or to optimize a tested concept, where the data used is that from a previous round of testing.

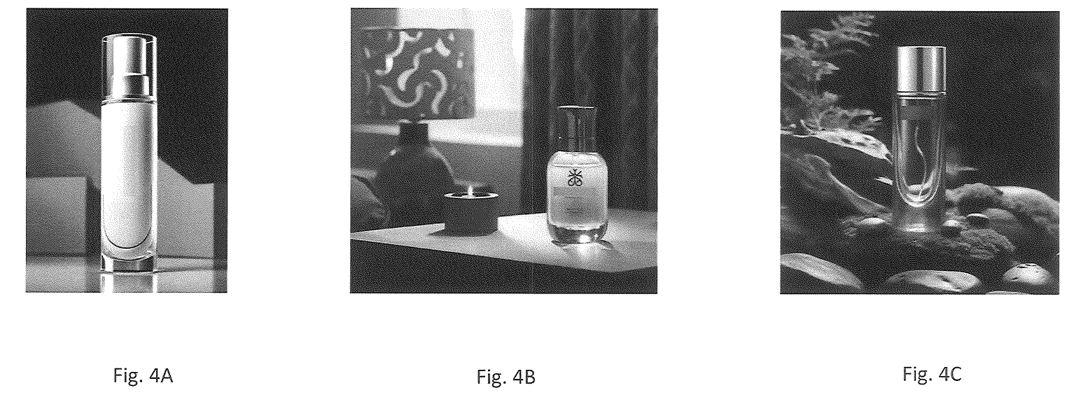

FIGS. 4A to 4C show exemplary outputs of designs for products (lubricants in this example) all obtained using the same generative AI engine. The designed outputs include an actual product container in each case but also an environment and background consistent with the inputs provided and the themes/insight data used.

FIG. 4A, “Euphorphase”, is a simple design that has been produced simply using generative AI, with a simple prompt. No contextual data has been used, either manually input or in any way generated automatically.

FIG. 4B, “KY Harmony”, which appears as a more refined product and as will be explained below quantitatively performs better in terms of appeal to potential users was generated using the same generative AI engine in combination with five existing concepts also used as input to the engine. The produced design and concept is more appealing than that produced only by the use of the engine with the prompt.

FIG. 4C, “Durex Elements, Natural Harmony”, shows a final example in which as well as the data used to generate the concept of FIG. 4B, factors or themes from an existing insight database were used to further improve the generated product design and concept. In the example shown the themes could be, say, “nature”, “water”, “simplicity”, “purity”, etc. Although these are in themselves subjective themes within the context of this example, the idea of use of themes is clear and would be well understood by a skilled person.

By using themes from an existing attitudinal data set the output of a generative AI system in terms of user experience and appreciation are improved. In the example described above, which example is not intended to be limiting, the coupling of such a process with manufacture provides a simple and reliable way of producing user-optimized product.

An optimized product design is thus generated automatically based on factors derived from an attitudinal data asset. The surface appearance and the three dimensional configuration of a product such as a container can interact significantly to determine how it is perceived by a user. The use of factors obtained from an attitudinal data set in combination with a generative AI engine ensures that the combination of the surface and three dimensional appearance of the generated product are optimized.

In the example shown the product concept generated and then the container manufactured is a bottle for a lubricant. The output generated here (FIG. 4C), which empirically is shown to be optimized as compared to the other examples, has had both its three dimensional shape and the color or surface appearance determined. In this case a transparent bottle of defined three dimensional shape has been generated as a concept and then manufactured. In practice although the example relates to a container for a lubricant, any type of container might have been generated. Indeed, products other than containers can also be generated. Fashion items, clothing accessories, food products, electronic items amongst many more, can all be outputs of the defined method.

Themes can be identified by taking individual verbatim responses against existing concepts, applying a clustering algorithm to groups responses of a similar nature, and then separately using the generative AI (e.g., OpenAI) to identify a theme that represents the cluster of verbatims. Examples includes “Packaging or branding concerns” or “Lack of detailed information”. Another source of themes can be category trackers that track various attributes specific to a category, and how respondents prioritize them (for example “Price”, “Packaging,” etc.).

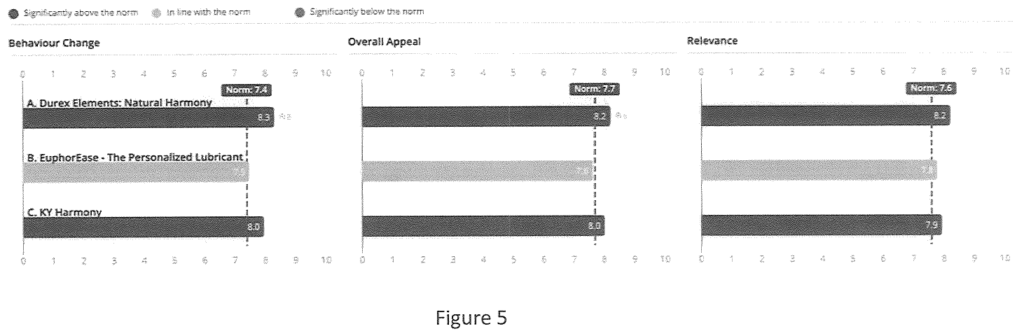

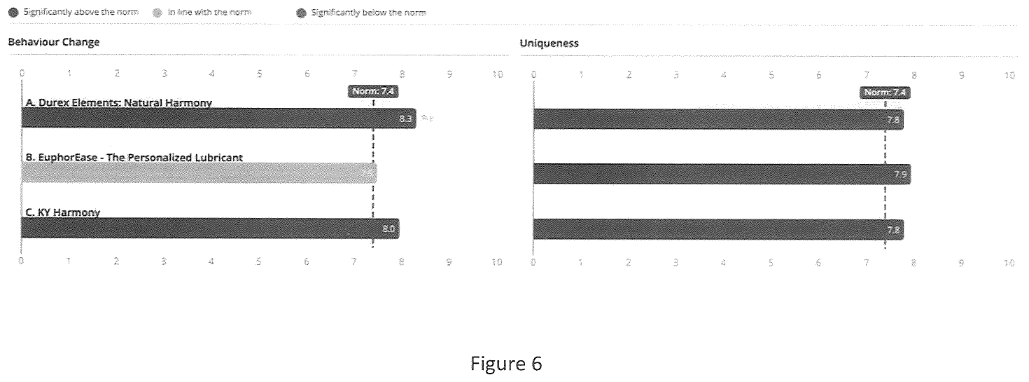

The three products/concepts were then examined in an insight study against a target group and results, shown in FIGS. 5 and 6, gathered. The results in respect of the three examples, labelled A to C in the bar charts of FIGS. 5 and 6, show that the Durex Elements, Natural Harmony concept, created using the method of the present invention performed better than the other two in all categories apart from uniqueness.

The results are substantially consistent across all measured parameters. For example, considering Overall Appeal (FIG. 5), the results show that the Durex Elements, Natural Harmony concept was 5% improved compared to the norm. For relevance, the Durex Elements, Natural Harmony concept was 4% improved compared to the norm, and for Behavior Change, it was 9% improved compared to the norm.

Significantly, the results for the Durex Elements, Natural Harmony concept as compared to the KY Harmony concept was also positive.

For overall appeal, the relative improvement with respect to the norm as compared to KY harmony's performance with respect to the norm was an improvement of 0.6 as compared to 0.4, i.e., a 50% improvement in the difference. For relevance, the relative improvement with respect to the norm as compared to KY Harmony's performance with respect to the norm was an improvement of 0.4 as compared to 0.1, i.e., a factor of 4 (0.4/0.1) relative improvement.

Overall, the use of a method of product design that combines generative AI with bespoke consumer insight enables significantly improved products to be designed and produced.

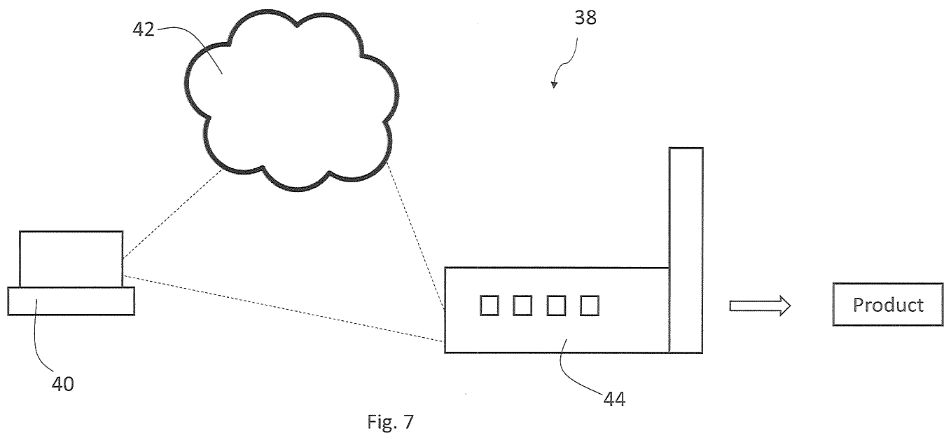

FIG. 7 shows schematically a representative system for product production using the method described herein. The system 38 comprises a user terminal 40 coupled either to a communications network 42 such as the internet or alternatively directly to a manufacturing facility 44. The user terminal 40 can be a computer arranged to run software to execute the method of product design described herein. Alternatively, it can be an interface arranged to couple to functionality hosted remotely, such as in the network 42. Either way the output of the process constitutes an optimized concept or product design (24 in FIG. 2, or 36 in FIG. 3), is preferably communicated to a manufacturing facility shown schematically 44.

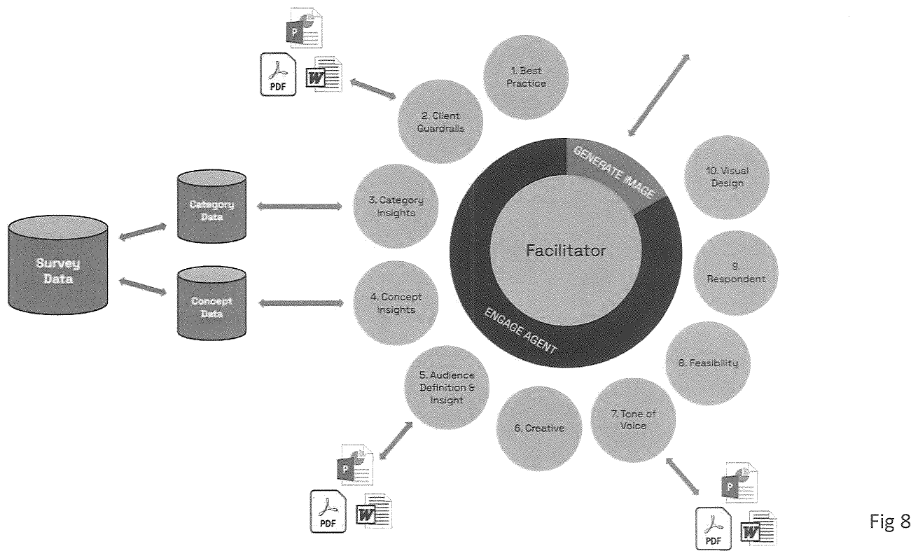

The process of concept or product generation is preferably executed in an automated manner using a structure of AI agents or AI generation, as will now be described. FIG. 8 is a schematic view of an exemplary set of AI agents used in the automated process of concept or product design generation. The AI agents are dedicated to specific tasks and the structuring of product or concept design generation in this manner breaks a concept or product design process into smaller parts while ensuring that, in a particular embodiment, specific agents are able to access the files, resources or APIs that are relevant to the specific task.

The process initially establishes a facilitator AI engine which controls or handles the interactions between the individual AI agents as will now be described. Typically, a number of agents will be utilized which will include an audience agent which is arranged and controlled to identify the target audience for a particular concept. A client agent is typically utilized and is provided to represent client specific context or validations. The client agent can be used to set expectations and to validate generated concepts at the end of the automated process.

Another agent is the creative agent. Preferably, this agent defines the concept and defines the structure of the concept. The definition might typically be done based on provided context, e.g. as might be derived based on the attitudinal data asset.

A feasibility agent is typically used to reign in unfeasible ideas and may be thought of as applying “common sense” to generated concepts.

As can be seen schematically in FIG. 8, one or more of the AI agents are arranged to exchange data with a survey data resource. This resource is what has been referred to herein as the attitudinal data asset. As can be seen schematically, the category insights agent and the concept insights agent are arranged to receive input from the attitudinal data asset which can then be used to drive or affect the concept or product generation from the automated system.

The list of exemplary agents provided herewith is not exhaustive. As can be seen in FIG. 8, a number of other AI agents might typically be available. Advantageously, the facilitator (shown as “engage agent”) is arranged to select or utilize the necessary agents for a particular concept generation process. What is important is the breakdown of the AI generated concept into a sequence or collection of functions or process specific AI agents. This simplifies the concept generation process. Furthermore, it is often the case that not all available agents will actually be required for a particular automated concept generation process. Thus, the process is efficient since unnecessary steps or activity by agents can be avoided. The facilitator agent is able to select only the AI agents that are needed for a particular concept generation. Typically, the agents are software-implemented.

Various of the agents are arranged to receive additional data inputs such as the “Client Guardrails” agent, which might be arranged to receive information from the client to prescribe features or limits of the concept or product design to be generated. Similarly, the “Audience Definition and Insight Agent” and the “Tone of Voice Agent” are preferably arranged to receive additional inputs as part of the automated process.

It will be appreciated that the process has a technical output itself in the form of the optimized product design, which is preferably communicated directly to the manufacturing facility or alternatively can be stored as an optimized design for manufacture at a desired time.

The techniques described herein may be implemented in a design and manufacturing system that is network-accessible and executes as a computing platform. Generalizing, one or more functions of the computing platform of this disclosure may be implemented in a cloud-based architecture. As is well-known, cloud computing is a model of service delivery for enabling on-demand network access to a shared pool of configurable computing resources (e.g. networks, network bandwidth, servers, processing, memory, storage, applications, virtual machines, and services) that can be rapidly provisioned and released with minimal management effort or interaction with a provider of the service. Available services models that may be leveraged in whole or in part include: Software as a Service (SaaS) (the provider's applications running on cloud infrastructure); Platform as a service (PaaS) (the customer deploys applications that may be created using provider tools onto the cloud infrastructure); Infrastructure as a Service (IaaS) (customer provisions its own processing, storage, networks and other computing resources and can deploy and run operating systems and applications). The platform may comprise co-located hardware and software resources, or resources that are physically, logically, virtually and/or geographically distinct. Communication networks used to communicate to and from the platform services may be packet-based, non-packet based, and secure or non-secure, or some combination thereof. In a more specific embodiment, the platform comprises a set of services, each of which is typically implemented as a set of one or more configurable computing resources (e.g. networks, network bandwidth, servers, processing, memory, storage, applications, virtual machines, and services).

Aspects of this disclosure may be practiced, typically in software, on one or more machines or computing devices. More generally, the techniques described herein are provided using a set of one or more computing-related entities (systems, machines, processes, programs, libraries, functions, or the like) that together facilitate or provide the described functionality described above. In a typical implementation, a representative machine on which the software executes comprises commodity hardware, an operating system, an application runtime environment, and a set of applications or processes and associated data, which provide the functionality of a given system or subsystem. As described, the functionality may be implemented in a standalone machine, or across a distributed set of machines. A computing device connects to the publicly-routable Internet, an intranet, a private network, or any combination thereof, depending on the desired implementation environment.

As noted, one or more functions of the computing platform may be implemented in a cloud-based architecture. The platform may comprise co-located hardware and software resources, or resources that are physically, logically, virtually and/or geographically distinct. Communication networks used to communicate to and from the platform services may be packet-based, non-packet based, and secure or non-secure, or some combination thereof.

Each above-described process or process step/operation preferably is implemented in computer software as a set of program instructions executable in one or more processors, as a special-purpose machine.

Representative machines on which the subject matter herein is provided may be hardware processor-based computers running an operating system and one or more applications to carry out the described functionality. One or more of the processes described above are implemented as computer programs, namely, as a set of computer instructions, for performing the functionality described. Virtual machines may also be utilized.

While the above describes a particular order of operations performed by certain embodiments of the invention, it should be understood that such order is exemplary, as alternative embodiments may perform the operations in a different order, combine certain operations, overlap certain operations, or the like. References in the specification to a given embodiment indicate that the embodiment described may include a particular feature, structure, or characteristic, but every embodiment may not necessarily include the particular feature, structure, or characteristic.

While the disclosed subject matter has been described in the context of a method or process, the subject matter also relates to apparatus for performing the operations herein. This apparatus may be a particular machine that is specially constructed for the required purposes, or it may comprise a computer otherwise selectively activated or reconfigured by a computer program stored in the computer. Such a computer program may be stored in a non-transitory computer readable storage medium, such as, but is not limited to, any type of disk including an optical disk, a CD-ROM, and a magnetic-optical disk, a read-only memory (ROM), a random access memory (RAM), a magnetic or optical card, or any type of media suitable for storing electronic instructions, and each coupled to a computer system bus.

There is no limitation on the type of computing entity that may implement a function or operation as described herein.

While given components of the system have been described separately, one of ordinary skill will appreciate that some of the functions may be combined or shared in given instructions, program sequences, code portions, and the like. Any application or functionality described herein may be implemented as native code, by providing hooks into another application, by facilitating use of the mechanism as a plug-in, by linking to the mechanism, and the like.

The functionality may be co-located, or various parts/components may be separately and run as distinct functions, and in one or more locations over a distributed network.

Computing entities herein may be independent from one another, or they may be associated with one another. Multiple computing entities may be associated with a single enterprise entity, but they are separate and distinct from one another.

The generative AI here may be accessed via the computing platform, e.g., from a network-accessible endpoint. A representative AI model may be OpenAI ChatGPT.

Generative artificial intelligence is artificial intelligence capable of generating text, images, or other media in response to prompts. Generative AI models learn the patterns and structure of their input training data by applying neural network machine learning techniques, and then generate new data that has similar characteristics. A large language model (LLM) is a language model generative AI characterized by emergent properties enabled by its large size. A typical LLM is built with artificial neural networks that are pre-trained using self-supervised learning and semi-supervised learning, and a model of this type may have tens of millions to billions of weights. As language models, a model of this type works by taking an input text and repeatedly predicting a next token or word. Known generative LLMs (GLLMs) include OpenAI GPT-4, LLaMA, and many others. Given appropriate training data, a GLLM can predict values in a given text.

What is claimed is set forth below.

1. A method of product concept modification, the method comprising:
configuring a set of software agents, the software agents configured to:
receive a product concept;
identify factors from on an attitudinal data asset in relation to the received product concept; and
provide the product concept and the factors as an input to generative Artificial Intelligence (AI) to produce a modified product concept.

2. The method according to claim 1, wherein the set of software agents are further configured to conduct consumer insight testing on the received product concept and providing output from the consumer insight testing to the generative AI together with the identified factors from the attitudinal data asset.

3. The method according to claim 1, wherein the set of software agents are further configured to provide the modified product concept as an input to a manufacturing process.

4. The method according to claim 1, wherein the set of software agents are configured in a cloud computing infrastructure remotely from a user terminal.

5. A method of generating a product concept, the method comprising:
identifying from an attitudinal data asset one or more factors relating to a concept to be created;
providing the one or more factors to a generative Artificial Intelligence (AI) and receiving a response; and
producing the product concept with the response received from the generative AI.

6. The method according to claim 5, wherein the one or more factors comprise themes for emphasis or de-emphasis in the product concept.

7. The method according to claim 5, further comprising providing the product concept to image generation application to generate corresponding imagery associated with the product concept.

8. The method according to claim 5, further including receiving an input that specifies one or more parameters or qualities associated with the product concept.

9. The method as described in claim 3, further including manufacturing a physical product in the manufacturing process according to the modified product design.

10. The method according to claim 9, wherein manufacturing the physical product further includes generating a data file specifying the modified product design, the data file specifying one or more of: features, components, ingredients, and parameters of the physical product to be manufactured in the manufacturing process.

11. A method of manufacture of a physical product, the method comprising:
generating a product design according to a product concept produced by identifying factors from an attitudinal data asset in relation to the product concept;
providing the product concept and the factors as an input to generative AI to produce a modified product concept relating to the product; and
manufacturing the product according to a design as defined in the modified product concept.

12. The method as described in claim 11, wherein the product is a container having an opening and body for storing a gas, liquid or solid.

13. The method as described in claim 12, in which the design includes one or more factors, wherein the factors are one of: physical dimensions of the container, and a surface appearance of the container.

14. The method as described in claim 13, wherein the surface appearance includes at least one of: a texture, a pattern, and a color.
